(19) United States
(12) Patent Application Publication
(10) Pub. No.: US 2008/0191343 A1
(43) Pub. Date: Aug. 14, 2008

(54) Integrated circuit package having large conductive area and method for fabricating the same

(75) Inventor: Chien-Hung Liu, Taoyuan (TW)

Correspondence Address: BIRCH STEWART KOLASCH & BIRCH, PO BOX 747, FALLS CHURCH, VA, 22040-0747, US

(73) Assignee: XinTec Inc.

(21) Appl. No.: 11/798,159

(22) Filed: May 10, 2007

(30) Foreign Application Priority Data
Feb. 13, 2007 (CN) 200710005733.4

(51) Int. Cl. H01L 23/48; H01L 21/98

(52) U.S. Cl. 257/723; 257/784; 438/127; 257/E23.01; 257/E21.705

(57) ABSTRACT

An integrated circuit package having large conductive area and method for fabricating the same is provided. The package includes an integrated circuit chip having upper and lower surfaces and a photosensitive device formed on the upper surface. A bonding pad is subsequently formed on the upper surface of the integrated circuit chip and electrically connected to the photosensitive device. A conductive layer is then formed on a sidewall of the integrated circuit chip and wrapped around an edge of the bonding pad to electrically connect to the bonding pad. In the package, the conductive layer is in contact with the upper and lower surfaces and a sidewall of the bonding pad. Because the conductive layer is wrapped around the edge of the bonding pad, contact surface and structural strength between the conductive layer and the bonding pad are increased.

### BACKGROUND OF THE INVENTION

1. Field of the Invention

The invention relates to integrated circuit packages, and more particularly relates to an integrated circuit package having improved conductivity and structural strength and the method for fabricating thereof.

2. Description of the Related Art

In the process of fabricating integrated circuit devices, an integrated circuit packaging step is performed. The integrated circuit can be wide variety of applications, including, computers, mobile phones or digital cameras. The performance of an integrated circuit device relates to the structure of the integrated circuit package.

FIG. 1 shows a conventional integrated circuit package 1. In FIG. 1, a photosensitive device 4 is formed on an integrated circuit chip 2, and electrically connected to a bonding pad 6. A protective layer 8 is then formed on the integrated circuit chip 2 and covers the bonding pad 6. A conductive layer 10 is formed on a sidewall of the integrated circuit chip 2 and electrically connected to the bonding pad 6, as shown in FIG. 1. In the conventional integrated circuit package, the conductive layer contacts a sidewall of the bonding pad, reducing, the conductive area between the bonding pad and the conductive layer. Structural strength between the bonding pad and the conductive layer is also reduced because the conductive layer is only in contact with the sidewall of the bonding pad.

Thus, an improved integrated circuit package and fabrication method thereof increasing the contact surface and structural strength between the conductive layer and the bonding pad is needed.

### BRIEF SUMMARY OF INVENTION

Accordingly, one aspect of the invention is to provide an integrated circuit package having high conductive area. The package comprises an integrated circuit chip having an upper and a lower surfaces and a photosensitive device formed on the upper surface; a bonding pad formed on the upper surface of the integrated circuit chip and electrically connected to the photosensitive device; and a conductive layer formed on a sidewall of the integrated circuit chip and wrapped around an edge of the bonding pad to electrically connect to the bonding pad.

Another aspect of the invention is to provide a method for fabricating an integrated circuit package having high conductive area. The method includes providing an integrated circuit chip having an upper and a lower surfaces and a photosensitive device form on the upper surface; forming a bonding pad on the upper surface of the integrated circuit and electrically connected to the photosensitive device; and forming a conductive layer on a sidewall of the integrated circuit chip and wrapped around the bonding pad to electrically connected to the bonding pad.

In the package, the conductive layer is in contact with the upper, lower surfaces and sidewall of the bonding pad because the conductive layer is wrapped around the edge of the bonding pad, to increase a contact surface between the conductive layer and the bonding pad for promoting conductive area between the conductive layer and the bonding pad. Additionally, a structural strength of a contact portion between the conductive layer and the bonding pad is increased because the conductive layer is wrapped around the edge of the bonding pad. Mechanical strength and firmness of the integrated circuit package.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 shows a cross sectional view of a conventional integrated circuit package; and

FIGS. 2A-2G show schematic views of fabricating an integrated circuit package according to an embodiment of the invention.

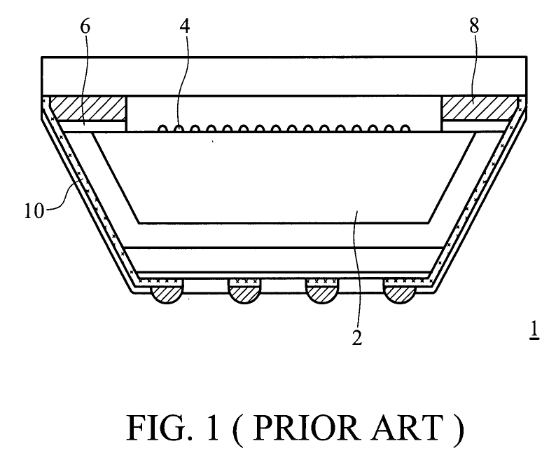

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

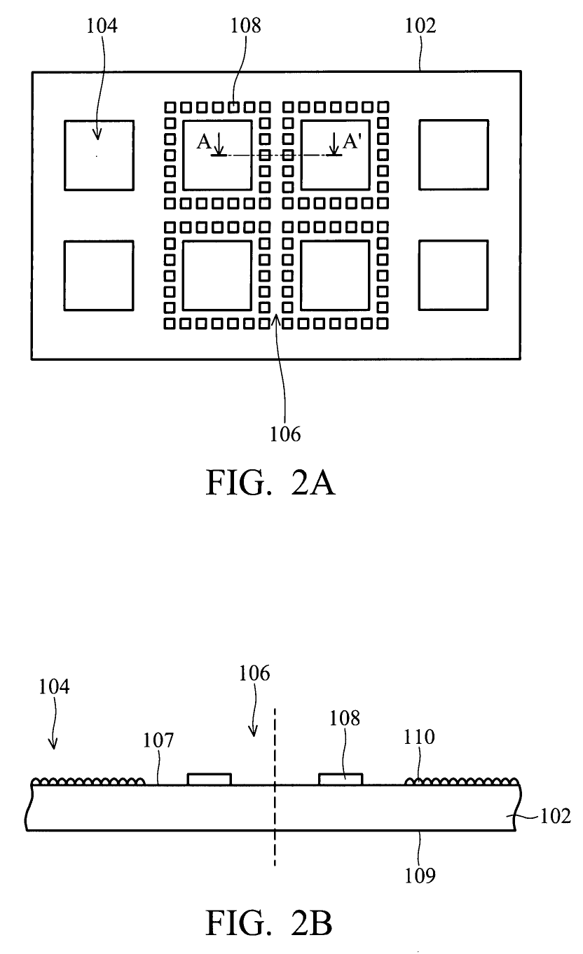

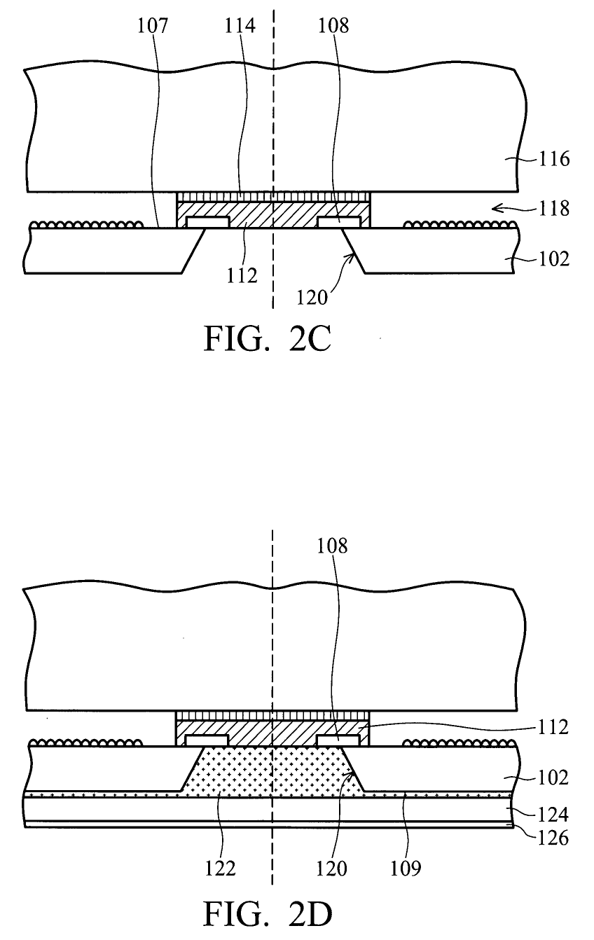

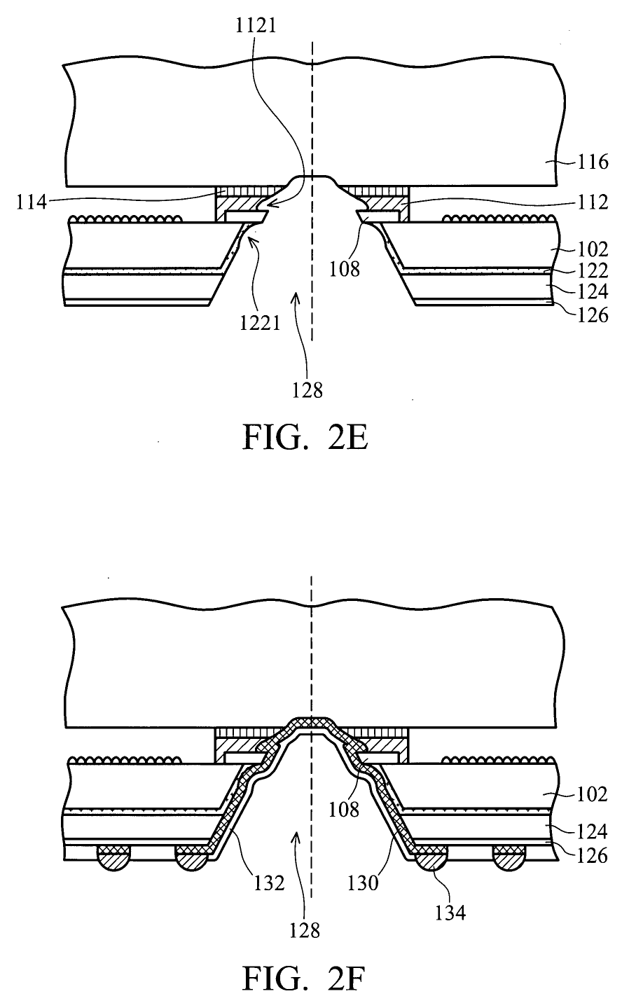

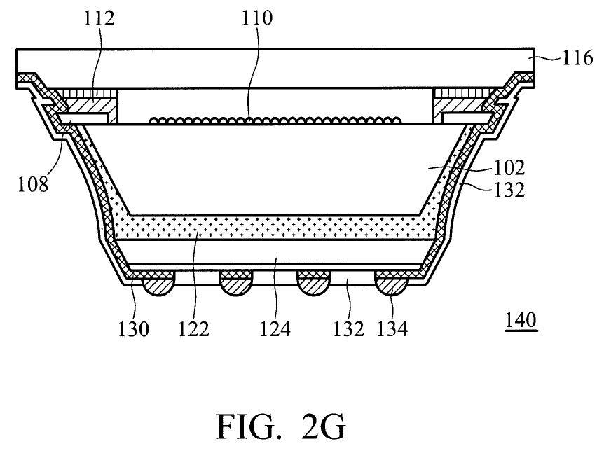

FIGS. 2A-2G show cross sectional views of fabricating an integrated circuit package according to an embodiment of the invention. FIG. 2A shows a top view of integrated circuit chip 102, wherein an upper surface of the integrated circuit chip 102 is divided into a central region 104 and a peripheral region 106. FIG. 2B shows a cross sectional view along A to A′ of FIG. 2A. In FIG. 2B, an integrated circuit chip 102 having an upper surface 107 and a lower surface 109 is provided. A photosensitive device 110 is disposed on the upper surface 107, in the central region 104 of the integrated circuit chip 102. A bonding pad is then formed on the upper surface 107, in the peripheral region 106 of the integrated circuit chip 102, and electrically connected to the photosensitive device 110. The bonding pad 108 may surround the photosensitive device 110 within the central region 104, as shown in FIG. 2A.

FIG. 2C, a protective layer 112, also referred to as a dam, is formed on the upper surface 107 of the integrated circuit chip 102 and covers the bonding pad 108 for protecting oxidation. A first substrate 116 is attached on the integrated circuit chip 102 by an adhesive layer 114, to form a gap 118 between the first substrate 116 and the integrated circuit chip 102. The first substrate 116 is also referred to as a covering plate.

The first substrate 116 may be a glass, quartz, opal, plastic or any suitable transparent material. Preferably, the protective layer 112 may be epoxy, polyimide (PI) or any suitable insulating material. The adhesive layer 114 may be an adhesive material containing epoxy.

In FIG. 2C, a portion of integrated circuit chip 102 is removed along a predetermined cutting line of the individual die by photolithographic and etching processes, to form an opening 120 for cutting individual die. The opening 120 may expose a lower surface of the bonding pad 108 and the protective layer 112. The etching process may be wet-etching or dry-etching.

A polishing step may optionally be performed prior to cutting the individual die, to thin the integrated circuit chip 102, facilitating cutting of individual die.

In FIG. 2D, a second substrate 124 is attached on the lower surface 109 of the integrated circuit chip 102 by a sealant 122. An insulating layer 126 is then formed on a lower surface of the second substrate 124. The sealant 122 may preferably be epoxy, polyimide or any suitable material. The second substrate 124 may be a material similar to the first substrate. Note that the second substrate may be an opaque material and may serve as a supporting plate for integrated circuit chip 102.

FIG. 2E, a notching step is performed along the predetermined cutting line of the individual die, to form a trench 128 and expose a sidewall of the sealant 122, bonding pad 108 and protective layer 112 and a surface of the first substrate 116. A portion of the protective layer 112 and the sealant 122 is removed, exposing a portion of the upper and lower surfaces of the bonding pad 108.

In some embodiments, the portion of the protective layer 112 and the sealant 122 in the trench 128 is removed by plasma etching using a gas, such as, oxygen (O₂) or carbon tetrafluoride (CF₄). A sidewall 1221 of the sealant 122 and a sidewall 1121 of the protective layer 112 may thus be drawn back exposing the upper and lower surfaces of the bonding pad 108, as shown in FIG. 2E.

In FIG. 2F, a conductive layer 130 is formed in the trench 128 and electrically connected to the bonding pad 108. In one embodiment, a metal layer such as copper, aluminum, nickel or any suitable material is formed on a lower surface of the insulating layer 126. The conductive layer 130 is then extended from a sidewall of the second substrate 124 and the integrated circuit chip 102 to the lower, upper and sidewall surfaces and wrapped around an edge of the bonding pad 108 by, for example, sputtering, electroless-plating or plating The metal layer is then patterned by photolithographic and etching processes to form the conductive layer 130. In another embodiment, sputtering is first used to form the metal layer on the lower surface of the insulating layer 126 followed by forming the metal layer in the trench 128 by electroless-plating, also referred to as chemical plating.

Because the edge of the bonding pad 108 is wrapped by the conductive layer 130 a contact surface therebetween is increased, conductivity between the conductive layer 130 and the bonding pad 108 is increased.

FIG. 2F, a solder mask 132 is formed on the conductive layer 130, to expose a portion of the conductive layer 130. A solder ball 134 is then formed on the exposed conductive layer 130. An individual die is then cut along the predetermined cutting line thereof by a cutter, after performing the described steps. Thus, fabrication of an integrated circuit package 140, as shown in FIG. 2G is complete.

In FIG. 2G, an integrated circuit chip 102 having a photosensitive device 110 and a bonding pad 108 formed thereon is provided. A protective layer 112 covers bonding pad 108. A first substrate 116 is then disposed on the integrated circuit chip 102, and a second substrate 124 is attached to a lower surface of the integrated circuit chip 102 by, a sealant. As shown in FIG. 2G a conductive layer 130 is subsequently formed on a sidewall of the integrated circuit chip 102, and wrapped around a sidewall of the bonding pad 108, electrically connecting the bonding pad 108. Thereafter, the conductive layer 130 is covered by a solder mask to expose a portion of the conductive layer 130. A solder ball is then formed on the conductive layer 130, exposed, and electrically connected to conductive layer 130 completing an integrated circuit package 140.

Note that a contact surface between the conductive layer and banding pad is increased because an edge of the bonding pad is wrapped by conductive layer contacting the upper, lower, and sidewall surfaces of the bonding pad, thus, the conductive area between the conductive layer and the bonding pad is increased. Additionally, a structural strength of contact portion between the conductive layer and the bonding pad is increased because the edge of the bonding pad is wrapped by the conductive layer, thus, mechanical strength and firmness of the integrated circuit package is increased.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An integrated circuit package having large conductive area, comprising:
an integrated circuit chip having an upper and a lower surfaces, and a photosensitive device formed on the upper surface;
a bonding pad formed on the upper surface of the integrated circuit chip and electrically connected to the photosensitive device; and
a conductive layer formed on a sidewall of the integrated circuit chip and wrapped around an edge of the bonding pad to electrically connect to the boding pad.

2. The package of claim 1, further comprising a substrate correspondingly disposed on the upper surface of the integrated circuit chip.

3. The package of claim1, further comprising a protective layer formed on a portion of an upper surface of the bonding pad.

4. The package of claim 3, further comprising a sealant formed on the lower surface of the integrated circuit chip and a portion of a lower surface of the bonding pad.

5. The package of claim 4, wherein the conductive layer is in contact with the upper, and lower surfaces and a sidewall of the bonding pad to wrap around the edge of the bonding pad.

6. The package of claim 3, wherein the protective layer comprises epoxy or polyimide.

7. The package of claim 4, wherein the sealant comprises epoxy or polyimide.

8. The package of claim 1, further comprising a solder mask formed on the conductive layer to form an exposed portion of the conductive layer.

9. The package of claim 8, further comprising a solder ball formed on the exposed portion of the conductive layer.

10. The package of claim 1, wherein the conductive layer comprises copper, aluminum or nickel.

11. A method for fabricating an integrated circuit package having high conductive area, comprising:
providing an integrated circuit chip having an upper and a lower surfaces, and a photosensitive device formed on the upper surface;
forming a bonding pad on the upper surface of the integrated circuit chip, and electrically connected to the photosensitive device; and
forming a conductive layer on a sidewall of the integrated circuit chip and wrapping the conductive layer around an edge of the bonding pad to electrically connect to the bonding pad.

12. The method of claim 11, further comprising correspondingly disposing a first substrate on the upper surface of the integrated circuit chip.

13. The method of claim 11, further comprising covering a protective layer on the bonding pad.

14. The method of claim 13, further comprising removing a portion of the integrated circuit chip to expose a lower surface of the bonding pad.

15. The method of claim 14, further comprising attaching a second substrate on the lower surface of the integrated circuit chip by a sealant, wherein the sealant covers the exposed lower surface of the bonding pad.

16. The method of claim 15, further comprising forming a trench to expose sidewalls of the protective layer, bonding pad and sealant.

17. The method of claim 16, further comprising removing a portion of the protective layer and the sealant after forming the trench to expose a portion of an upper and the lower surfaces of the bonding pad.

18. The method of claim 17, wherein removing the portion of the protective layer and the sealant is performed by plasma etching.

19. The method of claim 17, further comprising forming the conductive layer on the exposed upper, lower surfaces and sidewall of the bonding pad after removing the protective layer and sealant to wrap around the edge of the bonding pad.

20. The method of claim 11, further comprising forming a solder ball on the conductive layer.
